(19) United States
(12) Patent Application Publication
(10) Pub. No.: US 2012/0126431 A1
(43) Pub. Date: May 24, 2012

(54) SEMICONDUCTOR PACKAGE

(75) Inventors: Yong-Hoon KIM, Suwon-si (KR); So-Young LIM, Hwaseong-si (KR); In-Ho CHOI, Seoul (KR)

(73) Assignee: SAMSUNG ELECTRONICS CO., LTD., Suwon-si (KR)

(21) Appl. No.: 13/278,620

(22) Filed: Oct. 21, 2011

(30) Foreign Application Priority Data
Nov. 24, 2010 (KR) 10-2010-0117566

(51) Int. Cl. H01L 23/538

(52) U.S. Cl. 257/777; 257/E23.169

(57) ABSTRACT

A semiconductor package having improved EMI and crosstalk characteristics is provided. The semiconductor package includes a semiconductor package including a substrate, at least one first semiconductor chip formed on a top surface of the substrate and electrically connected to the substrate, and at least one second semiconductor chip formed on a top surface of the first semiconductor chip and electrically connected to the first semiconductor chip, wherein first and second conductive layers are formed on the top surfaces of the first semiconductor chip and the second semiconductor chip, respectively, and the first conductive layer and the second conductive layer are connected to a ground portion.

### CROSS-REFERENCE TO RELATED APPLICATION

This application claims priority from Korean Patent Application No. 10-2010-0117566 filed on Nov. 24, 2010, in the Korean Intellectual Property Office, the contents of which are herein incorporated by reference in their entirety.

### BACKGROUND

1. Field

The present exemplary embodiments relate to a semiconductor package, and more particularly to a semiconductor package having improved EMI and crosstalk characteristics.

2. Description of the Related Art

To realize miniaturization, lightness and slimness in electronic apparatuses, techniques for mounting semiconductor chips in high density have been developed. One of the techniques is multi-chip packaging technology in which a plurality of semiconductor chips are mounted on a single package. To enhance integration of a package, multi-chip packaging techniques in which a plurality of semiconductor chips are stacked and mounted have been introduced. Among multi-chip packages, a package in which a plurality of semiconductor chips having different functions are integrated into a single package embodied as a single system, which is called a system-in-package (SIP) technique, is being developed.

However, in the stack-type semiconductor package structure, individual chips radiate electromagnetic waves when in operation, causing crosstalk between electric signals of opposing semiconductor chips, resulting in noise that can cause significant electromagnetic interference (EMI). In particular, in a case where EMI occurs in a portable device, such as a hand-held phone (HHP), reception sensitivity may be lowered. Accordingly, there is an increasing demand for reduction in EMI.

### SUMMARY

The exemplary embodiments provide a semiconductor package having improved EMI and crosstalk characteristics.

The exemplary embodiments also provide a semiconductor package having improved EMI and crosstalk characteristics.

These and other aspects of the exemplary embodiments will be described in or be apparent from the following description of the exemplary embodiments.

According to an aspect of an exemplary embodiment, there is provided a semiconductor package including a substrate, at least one first semiconductor chip formed on a top surface of the substrate and electrically connected to the substrate, and at least one second semiconductor chip formed on a top surface of the first semiconductor chip and electrically connected to the first semiconductor chip, wherein first and second conductive layers are formed on the top surfaces of the first semiconductor chip and the second semiconductor chip, respectively, and the first conductive layer and the second conductive layer are connected to a ground portion.

According to another aspect of an exemplary embodiment, there is provided a semiconductor package including a substrate, at least one first semiconductor chip formed on a top surface of the substrate and electrically connected to the substrate by a first connection member, and at least one second semiconductor chip formed on a top surface of the first semiconductor chip and electrically connected to the first semiconductor chip by a second connection member, wherein first and second conductive layers are formed on the top surfaces of the first semiconductor chip and the second semiconductor chip, respectively, the second connection member includes at least one second ground connection member connected to a ground portion, and the first conductive layer and the second conductive layer are connected to the second ground connection member.

According to still another aspect of an exemplary embodiment, there is provided a semiconductor package including a substrate, at least one first semiconductor chip formed on a top surface of the substrate and electrically connected to the substrate by a first connection member, and at least one second semiconductor chip formed on a top surface of the first semiconductor chip and electrically connected to the first semiconductor chip by a second connection member, wherein first and second conductive layers are formed on the top surfaces of the first semiconductor chip and the second semiconductor chip, respectively, the second connection member includes at least one second ground connection member connected to a ground portion, the first conductive layer is connected to the second ground connection member, and the second conductive layer is connected to the first conductive layer.

According to a further aspect of an exemplary embodiment, there is provided a semiconductor package including: a substrate, at least one first semiconductor chip formed on a top surface of the substrate and electrically connected to the substrate by a first connection member, and at least one second semiconductor chip formed on a top surface of the first semiconductor chip and electrically connected to the first semiconductor chip by a second connection member, wherein first and second conductive layers are formed on the top surfaces of the first semiconductor chip and the second semiconductor chip, respectively, a third conductive layer connected to a ground portion is formed on the top surface of the substrate, and the first conductive layer or the second conductive layer is connected to the third conductive layer.

### BRIEF DESCRIPTION OF THE DRAWINGS

The above and other features and aspects of the exemplary embodiments will become more apparent by describing in detail exemplary embodiments thereof with reference to the attached drawings in which:

FIG. 1A and FIG. 1B are a cross-sectional view of a semiconductor package according to an exemplary embodiment;

FIG. 2 is a perspective view of a first semiconductor chip in the semiconductor package shown in FIG. 1A;

FIG. 3 is a cross-sectional view of a semiconductor package according to another exemplary embodiment;

FIG. 4 is a cross-sectional view of a semiconductor package according to still yet another exemplary embodiment; and

FIG. 5 is a cross-sectional view of a semiconductor package according to still yet another exemplary embodiment.

### DETAILED DESCRIPTION

Aspects and features of the exemplary embodiments and methods of accomplishing the same may be understood more readily by reference to the following detailed description of exemplary embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. In the drawings, the thickness of layers and regions are exaggerated for clarity.

It will be understood that when an element or layer is referred to as being “directly on” or “on” another element or layer, it can be directly on or connected to the other element or layer or intervening elements or layers may be present. Like numbers refer to like elements throughout. As used herein, the term “and/or” includes any and all combinations of one or more of the associated listed items.

Spatially relative terms, such as “below,” “beneath,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

Embodiments described herein will be described referring to plan views and/or cross-sectional views by way of ideal schematic views of the invention. Accordingly, the exemplary views may be modified depending on manufacturing technologies and/or tolerances. Therefore, the embodiments of the invention are not limited to those shown in the views, but include modifications in configuration formed on the basis of manufacturing processes. Therefore, regions exemplified in figures have schematic properties and shapes of regions shown in figures exemplify specific shapes of regions of elements and not limit aspects of the invention.

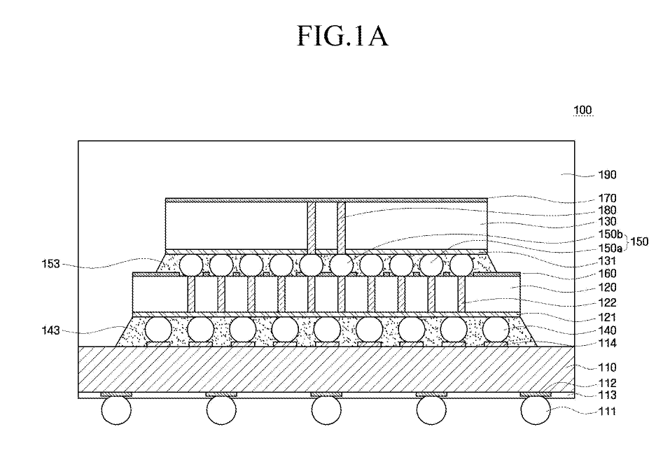

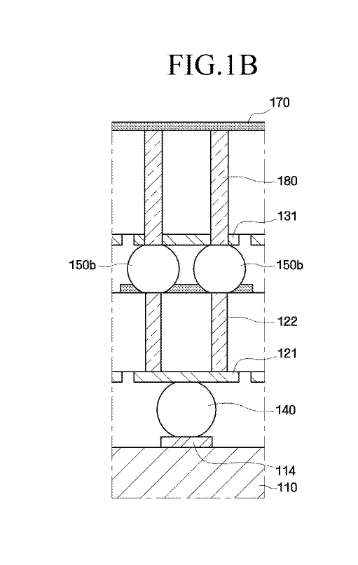

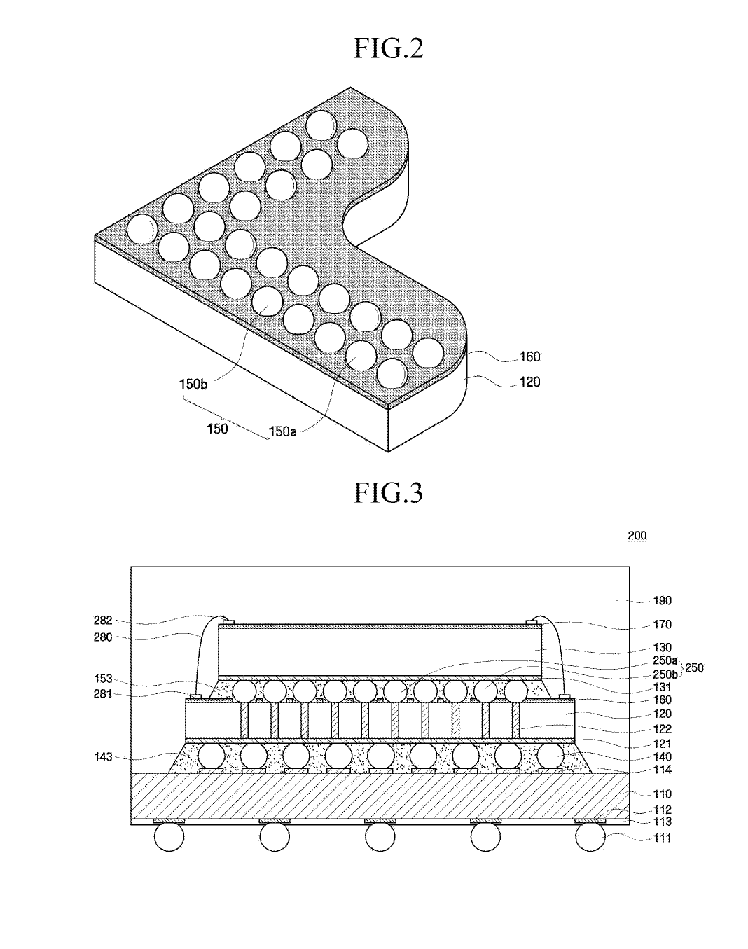

Hereinafter, exemplary embodiments will be described in detail with reference to the accompanying drawings. First, a semiconductor package according to an exemplary embodiment will be described with reference to FIGS. 1A to 2. FIG. 1A and FIG. 1B are a cross-sectional view of a semiconductor package 100 according to an exemplary embodiment and FIG. 2 is a perspective view of a first semiconductor chip 120 in the semiconductor package 100 shown in FIG. 1A.

Referring to FIG. 1A, the semiconductor package 100 according to the exemplary embodiment uses a substrate 110 as a stacking base and includes a first semiconductor chip 120, a second semiconductor chip 130, a first connection member 140, a second connection member 150, a first conductive layer 160, a second conductive layer 170 and an encapsulation member 190.

The substrate 110 may be formed by forming a wiring layer on an insulating layer. The wiring layer is capable of transmitting electrical signals, and the insulating layer may be formed of a thin plate made of an inorganic or organic material. Examples of the inorganic thin plate suitably used to form the substrate 110 may include a resin film, a resin impregnated glass fiber base member, ceramic, and other insulating materials.

The substrate 110 has a substantially plate-like shape. Although not shown, the substrate 110 may include a plurality of through-holes passing through the substrate 110 and a plurality of circuit patterns. In an exemplary embodiment, the through-holes include conductive elements. The circuit patterns may be electrically connected to the through-holes.

Connection terminals 111 electrically connected to an external device may be formed on a bottom surface of the substrate 110. The connection terminals 111 may include, for example, solder balls or conductive bumps. When a semiconductor package is mounted on another semiconductor package or an external device, the connection terminals 111 may facilitate electrical, mechanical connection between the semiconductor packages or between the semiconductor package and the external device. While FIG. 1A illustrates that the connection terminals 111 are solder balls, the exemplary embodiments are not limited thereto. The connection terminals 111 may be made of gold, silver, nickel, copper, tin, alloys thereof, or other conductive materials. Specifically, the connection terminals 111 may be made of, for example, copper-nickel-lead (Cu—Ni—Pb), copper-nickel-gold (Cu—Ni—Au), copper-nickel, nickel-gold, or nickel-silver.

In addition, connection pads 112 may be disposed between the substrate 110 and the connection terminals 111. The connection pads 112 electrically connect the substrate 110 and the connection terminals 111 and are formed to reduce conductive resistance. Specifically, the connection pads 112 may be made of a highly conductive metal, for example, copper, aluminum, nickel, platinum, silver, gold, alloys thereof, or other conductive materials.

An insulation layer 113 covering the bottom surface of the substrate 110 while exposing the connection pads 112 may be formed on the bottom surface of the substrate 110. However, the insulation layer 113 may not be formed, when necessary.

The first semiconductor chip 120 is stacked on the substrate 110 and electrically connected to the substrate 110. Although not shown, the first semiconductor chip 120 has a semiconductor element formed therein.

At least one of the first semiconductor chip 120 may be stacked on the substrate. FIG. 1A illustrates an example case where one first semiconductor chip 120 is stacked on the substrate.

The first semiconductor chip 120 means a circuit having a plurality of transistors, resistors, capacitors, etc. integrated on a silicon substrate, and performs operations of controlling devices, storing information, etc. In detail, the first semiconductor chip 120 may be a logic analog chip. Here, the logic analog chip includes a logic analog circuit. In general, the number of logic analog chips is greater than that of memory chips. Thus, for facilitating wire bonding, the logic analog chips among a plurality of semiconductor chips stacked on a substrate are positioned at a bottommost layer above the substrate.

A first redistribution layer 121 may be formed on a bottom surface of the first semiconductor chip 120. One surface of the first redistribution layer 121 is electrically connected to a first via 122 formed in the first semiconductor chip 120 and the other surface of the first redistribution layer 121 is electrically connected to the first connection member 140. Thus, the first via 122 and the first connection member 140 are electrically connected by the first redistribution layer 121. The first redistribution layer 121 may be made of a conductive material, such as silver, copper, aluminum, alloys thereof, but not limited thereto and may include other conductive materials.

The first via 122 is formed to pass through the top and bottom surfaces of the first semiconductor chip 120 and connects wirings between the semiconductor chips. The first via 122 may include a plurality of first through-holes spaced apart from each other. Specifically, the first via 122 may be of a cylindrical shape, a cylindrical rod, or a barrel shape, but not is limited thereto. The first via 122 may be formed using a through silicon via (TSV) process. The interior of the first via 122 may be filled with a conductive material to electrically connect the first semiconductor chip 120, the substrate 110 and the second semiconductor chip 130.

The first connection member 140 is interposed between the first semiconductor chip 120 and the substrate 110 and electrically connects the substrate 110 and the first semiconductor chip 120. Contact pads 114 in contact with the first connection member 140 may be formed on the top surface of the substrate 110. However, the contact pads 114 may not be formed, when necessary. The contact pads 114 may be made of a highly conductive metal which may be one of or a combination of copper, aluminum, nickel, platinum, silver, gold and other similar materials.

Specific examples of the first connection member 140 may include, but not limited to, conductive bumps, solder balls, etc.

A first underfill 143 is formed in a space between the first semiconductor chip 120 and the substrate 110. A first underfill 143 is formed by injecting a liquid resin material into a space between the first semiconductor chip 120 and the substrate 110, followed by curing. The first underfill 143 improves bonding capability and heat transfer capability while supporting the first semiconductor chip 120. Exemplary materials useful as the underfill may be one of or a combination of epoxy, benzocyclobutene (BCB), polyimide, and other similar materials. However, the first underfill 143 may not be formed, if necessary.

The second semiconductor chip 130 is stacked on the first semiconductor chip 120. Like the first semiconductor chip 120, at least one of the second semiconductor chip 130 may be stacked on the substrate. FIG. 1A illustrates an example case where one second semiconductor chip 130 is stacked on the substrate.

That is to say, the semiconductor package 100 according to the exemplary embodiments embodiment is configured such that a plurality of different or identical semiconductor chips 120 and 130 are sequentially stacked on the substrate 110 having conductive wirings formed thereon.

The second semiconductor chip 130 may be configured such that an integrated circuit (not shown) is formed on a silicon substrate. Specifically, the second semiconductor chip 130 may be a memory chip. The memory chip may be included a memory circuit.

The second semiconductor chip 130 may be electrically connected to the first semiconductor chip 120 by the second connection member 150. The second connection member 150 is interposed between the first semiconductor chip 120 and the second semiconductor chip 130 and electrically connects the first semiconductor chip 120 and the second semiconductor chip 130. Specific examples of the second connection member 150 may include, but not limited to, conductive bumps, solder balls, etc.

The second connection member 150 includes at least one second signal connection member 150a for transmitting signals, and at least one second ground connection member 150b electrically connected to a ground portion (not shown) of the substrate 110.

Specific examples of the second ground connection member 150b may include, but not limited to, conductive bumps, solder balls, etc., and the second ground connection member 150b may ground electric current.

A second redistribution layer 131 may be formed on a bottom surface of the second semiconductor chip 130. One surface of the second redistribution layer 131 may be electrically connected to wirings formed on the second semiconductor chip 130, and the other surface of the second redistribution layer 131 may be electrically connected to the second connection member 150. Therefore, the wirings of the second semiconductor chip 130 and the second connection member 150 are electrically connected by the second redistribution layer 131.

A second underfill 131 may be formed a space between the first semiconductor chip 120 and the second semiconductor chip 130. A second underfill 131 fills a space between the first semiconductor chip 120 and the second semiconductor chip 130, and improves bonding capability and heat transfer capability while supporting the second semiconductor chip 130. The second underfill 131 may be formed in the same manner as the first underfill 143, and may not be formed if necessary.

A first conductive layer 160 and a second conductive layer 170 are formed on top surfaces of the sequentially stacked first and second semiconductor chips 120 and 130 respectively. That is, a first conductive layer 160 is formed on top surfaces of the first semiconductor chips and a second conductive layer 170 is formed on top surfaces of the second semiconductor chips. FIG. 1A illustrates an exemplary case where the first semiconductor chip 120 and the second semiconductor chip 130 are formed singly, i.e., there is only one first semiconductor chip 120 and there is only one second semiconductor chip 130. However, the first semiconductor chip 120 and the second semiconductor chip 130 may be formed in a plurality. In this case, a conductive layer may be formed on a top surface of each of the plurality of first and second semiconductor chips. In an exemplary embodiment, the first and the second conductive layers 160 and 170 may be conductive plates.

The first conductive layer 160 and the second conductive layer 170 are connected directly or indirectly to a ground portion (not shown) of the substrate 110. FIG. 1A illustrates an exemplary case where the first conductive layer 160 and the second conductive layer 170 are connected to the ground portion such that they are connected to the first ground connection member 150b connected to the ground portion of the substrate 110.

As described above, in a stacked semiconductor chip structure in which a conductive layer is formed on each of the semiconductor chips, electromagnetic waves generated from each semiconductor chip can be absorbed by the conductive layer and emitted through the ground portion, thereby preventing or at least substantially reducing EMI. In addition, crosstalk that may be generated between different or identical semiconductor chips can be improved. Further, since a relatively wide area is connected to the ground portion, electrostatic discharge characteristic can be improved.

The first conductive layer 160 is formed on the top surface of the first semiconductor chip 120, and a thickness thereof can be optionally adjusted by one skilled in the art as long as the aspect of the exemplary embodiment is not harmed. As shown in FIGS. 1 and 2, the first conductive layer 160 is in contact with only the second ground connection member 150b but not in contact with the second signal connection member 150a among the second connection member 150. FIG. 2 illustrates that the first conductive layer 160 formed on the first semiconductor chip 120 is spaced a predetermined distance apart from the second signal connection member 150a and is in contact with the second ground connection member 150b. Thus, the first conductive layer 160 absorbs electromagnetic waves generated from the first semiconductor chip 130 and emits the same to the ground portion without interrupting signal transmission, thereby suppressing or at least substantially reducing EMI.

The first conductive layer 160 may be formed of a conductive material, and specific examples thereof may include, but not limited to, silver, copper, aluminum, nickel and gold, singly or in combination.

The second conductive layer 170 is formed on the top surface of the second semiconductor chip 130, absorbs electromagnetic waves generated from the second semiconductor chip 130, and is connected directly or indirectly to a ground portion (not shown) of the substrate 110. The second conductive layer 170 is connected to the ground portion and emits the electromagnetic waves generated from the semiconductor chips, thereby suppressing or at least substantially reducing EMI. FIG. 1A illustrates that the second conductive layer 170 is connected to the second ground connection member 150b to then be connected to the ground portion of the substrate 110.

The second conductive layer 170 is connected to the second ground connection member 150b through a second via 180. One or more of the second ground connection member 150b may exist between the first semiconductor chip 120 and the second semiconductor chip 130. In a case where the second ground connection member 150b exists in plurality, the second conductive layer 170 may be connected to one or more of the second ground connection member 150b. The second conductive layer 170 may be made of a conductive material, and may be formed of the same material as the first conductive layer 160.

The second vial 80 is formed to pass through the top and bottom surfaces of the second semiconductor chip 13. The second vial 80 connects the second conductive layer 170 and the second ground connection member 150b. In a case where the second ground connection member 150b exists in plurality, the second via 180 may also be formed in plurality. The second vial 80 may be formed using a through silicon via (TSV) process. The interior of the second vial 80 may be filled with a conductive material. Specifically, the second vial 80 may be of a cylindrical shape, a cylindrical rod, or a barrel shape, but not limited thereto.

Although not shown, a third conductive layer (not shown) may be formed on the substrate 110. The third conductive layer formed on the substrate 110 may be connected to a ground portion of the substrate 110. The third conductive layer absorbs electromagnetic waves generated from the substrate 110, thereby suppressing or at least substantially reducing EMI. The third conductive layer may be formed in the same method as the first conductive layer 160 and the second conductive layer 170.

The encapsulation member 190 is formed on the substrate 110 so as to encapsulate the first semiconductor chip 120 and the second semiconductor chip 130. The encapsulation member 190 may protect semiconductor chips from external physical shocks or moisture while maintaining the external shape of the semiconductor package 100. As shown in FIG. 1A, the encapsulation member 190 may entirely cover the substrate 110, however, the encapsulation member 190 may partially cover the substrate 110. The encapsulation member 190 may be formed by a molding process using one of or a combination of general epoxy resin, silicon resin, and equivalents thereof.

As described above, in the semiconductor package 100 according to the exemplary embodiment, a conductive layer is separately formed on top surfaces of the first semiconductor chip 120 and the second semiconductor chip 130, which are sequentially stacked, to then be connected to a ground connection member among connection members connecting the first semiconductor chip 120 and the second semiconductor chip 130, thereby allowing the conductive layer to absorb and emit electromagnetic waves generated from the respective semiconductor chips, thereby suppressing or at least substantially reducing EMI and crosstalk between the semiconductor chips.

Hereinafter, a configuration in which the first conductive layer 160 and the second conductive layer 170 are connected to the ground portion of the substrate 110 in the semiconductor package 100 according to the embodiment of the present invention will be described in detail with reference to FIG. 1B. Referring to FIG. 1B, the first conductive layer 160 is in direct contact with the second connection member 150b, and the second conductive layer 170 is electrically connected to the second connection member 150b through the second via 180 and the second redistribution layer 131. The second connection member 150b may be connected to the first connection member 140 through the first via 122 and the first redistribution layer 121. The first connection member 140 may be connected to the ground portion of the substrate through the contact pads 114. In this case, the contact pads 114 may be ground pads connected to the ground portion of the substrate. The ground portion of the substrate may be a ground line formed in the substrate, and the ground line may be connected to a ground portion of an external device. The first redistribution layer 121 and the second redistribution layer 131 connected to the second connection member 150b are insulated from redistribution layers connected to other connection members, respectively.

Hereinafter, a semiconductor package 200 according to another exemplary embodiment will be described with reference to FIG. 3. FIG. 3 is a cross-sectional view of a semiconductor package according to another exemplary embodiment.

Compared to the semiconductor package 100 shown in FIG. 1A, the semiconductor package 200 is substantially the same as the semiconductor package 100 in view of configuration and function, except that a first conductive layer 160 formed on the first semiconductor chip 120 and a second conductive layer 170 formed on the second semiconductor chip 130 are connected to a conductive wire 280. Accordingly, the same functional component is denoted by the same reference numeral, and the following description will be made with regard to components different from those of the semiconductor package 100 shown in FIG. 1A, including the conductive wire 280.

Referring to FIG. 3, the semiconductor package 200 uses a substrate 110 as a stacking base and includes a first semiconductor chip 120, a second semiconductor chip 130, a first connection member 140, a second connection member 250, a first conductive layer 160, a second conductive layer 170, an encapsulation member 190, and the conductive wire 280.

That is to say, a plurality of different or identical semiconductor chips are stacked on the substrate 110 having conductive wirings (not shown) formed thereon, and the first conductive layer 160 and the second conductive layer 170 are electrically connected through the conductive wire 280.

The substrate 110 and the first semiconductor chip 120 are electrically connected by the first connection member 140, and the first semiconductor chip 120 and the second semiconductor chip 130 are electrically connected by the second connection member 250. Here, the second connection member 250 includes at least one second signal connection member 250a for transmitting signals, and at least one second ground connection member 250b electrically connected to a ground portion (not shown) of the substrate 110.

A first conductive layer 160 and a second conductive layer 170 are formed on top surfaces of the first and second semiconductor chips 120 and 130, and absorb electromagnetic waves generated from the first semiconductor chip 120 and the second semiconductor chip 130.

The first conductive layer 160 is connected to the second ground connection member 250b among the second connection member 250 but is not connected to the second signal connection member 250a among the second connection member 250. Therefore, in a case where electromagnetic waves are generated from the first semiconductor chip 120, they may flow into a ground portion through the second ground connection member 250b, thereby preventing the electromagnetic waves from flowing out and ultimately suppressing or at least substantially reducing EMI.

The second conductive layer 170 is electrically connected to the first conductive layer 160 through the conductive wire 280. More specifically, a first semiconductor chip pad 281 formed on the first conductive layer 160 and a second semiconductor chip pad 282 formed on the second conductive layer 170 are electrically connected through the conductive wire 280. The first semiconductor chip pad 281 and the second semiconductor chip pad 282 may be made of a conductive material, such as aluminum, copper, nickel, palladium, silver, or gold. In addition, in a case where the first semiconductor chip 120 is larger than the second semiconductor chip 130, the first semiconductor chip pad 281 is exemplarily formed at a lateral portion of the substrate 110 not overlapping the second semiconductor chip 130, i.e., a lateral portion of the substrate 110 that is not covered by the second semiconductor chip 130, for facilitating bonding. The conductive wire 280 may be made of one of or a combination of gold, aluminum, copper and equivalents thereof, but not limited thereto.

The first conductive layer 160 is grounded in contact with the second ground connection member 150b, and the second conductive layer 170 is also grounded through the first conductive layer 160. In such a manner, the electromagnetic waves generated from the first semiconductor chip 120 and the second semiconductor chip 130 flow out through the ground portion, thereby suppressing or at least substantially reducing EMI and reducing noises due to crosstalk between semiconductor chips.

A third conductive layer (not shown) is further formed on the substrate 110, so that the third conductive layer is connected to the ground portion, thereby absorbing electromagnetic waves generated from the substrate 110 to suppress or at least substantially reducing EMI.

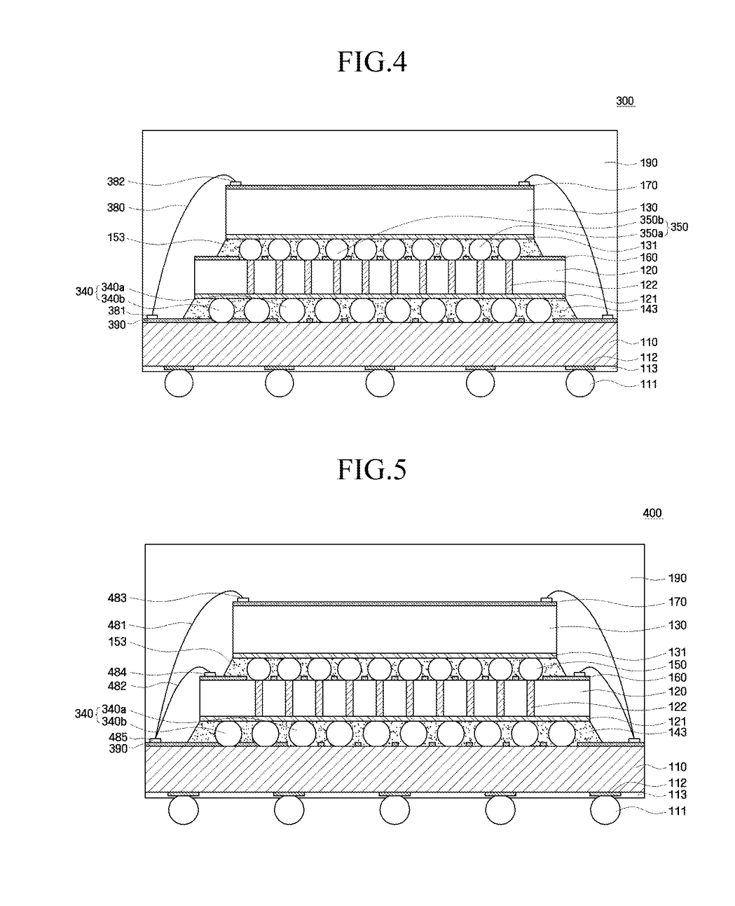

Hereinafter, a semiconductor package 300 according to still another exemplary embodiment will be described with reference to FIG. 4. FIG. 4 is a cross-sectional view of a semiconductor package according to still another exemplary embodiment.

Compared to the semiconductor package 100 shown in FIG. 1A, the semiconductor package 300 is substantially the same as the semiconductor package 100 in view of configuration and function, except that a second conductive layer 170 formed on a second semiconductor chip 130 and a third conductive layer 390 formed on a substrate 110 are connected to a conductive wire 380. Accordingly, the same functional component is denoted by the same reference numeral, and the following description will be made with regard to components different from those of the semiconductor package 100 shown in FIG. 1A, including the third conductive layer 390 and the conductive wire 380.

Referring to FIG. 4, the semiconductor package 300 uses the substrate 110 as a stacking base and includes a first semiconductor chip 120, a second semiconductor chip 130, a first connection member 340, a second connection member 350, a first conductive layer 160, a second conductive layer 170, the third conductive layer 390, the conductive wire 380 and an encapsulation member 190.

The substrate 110 and the first semiconductor chip 120 are electrically connected by the first connection member 340, and the first semiconductor chip 120 and the second semiconductor chip 130 are electrically connected by the second connection member 350. Here, the first connection member 340 includes at least one first signal connection member 340a for transmitting signals, and at least one first ground connection member 340b electrically connected to a ground portion (not shown) of the substrate 110. In addition, the second connection member 350 includes at least one second signal connection member 350a for transmitting signals, and at least one second ground connection member 350b electrically connected to the ground portion (not shown) of the substrate 110.

The third conductive layer 390 is formed on the substrate 110 using a conductive material, and a thickness thereof may be optionally adjusted by one skilled in the art as long as the aspect of the exemplary embodiment is not harmed. The third conductive layer 390 is in contact with the first ground connection member 340b but not in contact with the first signal connection member 340a. The third conductive layer 390 absorbs electromagnetic waves generated from the substrate 110 and allows the absorbed electromagnetic waves to flow out to the ground portion, thereby suppressing or at least substantially reducing EMI and reducing noises due to crosstalk between semiconductor chips.

The first conductive layer 160 formed on the first semiconductor chip 120 absorbs the electromagnetic waves generated from the first semiconductor chip 120. The first conductive layer 160 is not connected to the second signal connection member 350a but is connected to the second ground connection member 350b to ground the electromagnetic waves, thereby suppressing or at least substantially reducing EMI.

The second conductive layer 170 is connected to the third conductive layer 390 through the conductive wire 380 connecting a substrate pad 381 formed on the substrate 110 and a second semiconductor chip pad 382 formed on the second conductive layer 170. Here, since the third conductive layer 390 is connected to the first ground connection member 340b to then be grounded, the second conductive layer 170 is also grounded.

In such a manner, the EMI generated from the substrate 110 and the respective semiconductor chips 120 and 130 may be suppressed or at least substantially reduced and crosstalk between the semiconductor chips 120 and 130 may also be improved.

Hereinafter, a semiconductor package 400 according to still another exemplary embodiment will be described with reference to FIG. 5. FIG. 5 is a cross-sectional view of a semiconductor package according to still another exemplary embodiment.

Compared to the semiconductor package 300 shown in FIG. 4, the semiconductor package 400 is substantially the same as the semiconductor package 300 in view of configuration and function, except that a first conductive layer 160 and a second conductive layer 170 are electrically connected to a third conductive layer 390 through conductive wires 481 and 482. Accordingly, the same functional component is denoted by the same reference numeral, and the following description will be made with regard to components different from those of the semiconductor package 300 shown in FIG. 4, including the conductive wires 481 and 482.

Referring to FIG. 5, the semiconductor package 400 uses the substrate 110 as a stacking base and includes a first semiconductor chip 120, a second semiconductor chip 130, a first connection member 340, a second connection member 150, a first conductive layer 160, a second conductive layer 170, a third conductive layer 390, a first conductive wire 481, a second conductive wire 482 and an encapsulation member 190.

The third conductive layer 390 is not connected to a first signal connection member 340a but is connected to a first ground connection member 340b, to absorb electromagnetic waves generated from the substrate 110, thereby allowing the absorbed electromagnetic waves to flow out to a ground portion.

The second conductive layer 170 is connected to the third conductive layer 390 through the first conductive wire 481 connecting a substrate pad 485 formed on the substrate 110 and a second semiconductor chip pad 483 formed on the second conductive layer 170. Here, since the third conductive layer 390 is connected to a ground portion, the second conductive layer 170 is grounded through the third conductive layer 390. In such a manner, the EMI generated from the second semiconductor chip 130 may be suppressed or at least substantially reduced. For facilitating bonding, the substrate pad 485 is exemplarily formed at a lateral portion of the substrate 110 not overlapping the first semiconductor chip 130, i.e., formed at a lateral portion of the substrate 110 that is not covered by the first semiconductor chip 130.

The first conductive layer 160 is connected to the third conductive layer 390 through the second conductive wire 482 connecting the substrate pad 485 formed on the substrate 110 and a first semiconductor chip pad 484 formed on the first conductive layer 160. Here, since the third conductive layer 390 is connected to the first ground connection member 340b to then be grounded, the first conductive layer 170 is also grounded. In such a manner, the EMI generated from the first semiconductor chip 160 may also be suppressed or at least substantially reduced.

As described above, the semiconductor package according to the exemplary embodiments is constructed such that different or identical types of semiconductor chips are stacked. Each of the stacked semiconductors chips includes a conductive layer capable of absorbing electromagnetic waves generated from the chips. In addition, each of the conductive layers is connected to a ground portion, thereby preventing the electromagnetic waves from being emitted to the outside. Therefore, according to the exemplary embodiments, EMI can be suppressed or at least substantially reduced and noises due to crosstalk can be reduced. In addition, an electrostatic discharge characteristic can be improved.

While the present invention has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims rather than the foregoing description to indicate the scope of the invention.

What is claimed is:

1. A semiconductor package comprising:
a substrate,
a first semiconductor chip formed on a top surface of the substrate and electrically connected to the substrate, and
a second semiconductor chip formed on a top surface of the first semiconductor chip and electrically connected to the first semiconductor chip,
wherein a first conductive layer and a second conductive layer are formed on a top surface of the first semiconductor chip and on a top surface of the second semiconductor chip, respectively, and the first conductive layer and the second conductive layer are connected to a ground portion.

2. The semiconductor package of claim 1, wherein the first semiconductor chip is a logic chip.

3. The semiconductor package of claim 2, wherein the second semiconductor chip is a memory chip.

4. The semiconductor package of claim 1, wherein a third conductive layer is formed on the substrate and the third conductive layer is connected to the ground portion.

5. The semiconductor package of claim 1, further comprising:
a first connection member disposed between the substrate and the first semiconductor chip, electrically connecting the substrate and the first semiconductor chip, and
a second connection member disposed between the first semiconductor chip and the second semiconductor chip, electrically connecting the first semiconductor chip and the second semiconductor chip,
wherein the second connection member comprises a second ground connection member connected to the ground portion, and the first conductive layer and the second conductive layer are connected to the second ground connection member.

6. The semiconductor package of claim 5, wherein the second conductive layer is connected to the second ground connection member by a through-hole passing through the top surface and a bottom surface of the second semiconductor chip.

7. The semiconductor package of claim 5, wherein the first conductive layer is in contact with the second ground connection member.

8. The semiconductor package of claim 7, wherein the second connection member further comprises a second signal connection member, and the first conductive layer is not in contact with the second signal connection member.

9. The semiconductor package of claim 5, further comprising a through-hole passing through the top surface and a bottom surface of the first semiconductor chip and connected to the first connection member and the second connection member.

10. A semiconductor package of claim 1, further comprising:
a first connection member disposed between the substrate and the first semiconductor chip, electrically connecting the substrate and the first semiconductor chip, and
a second connection member disposed between the first semiconductor chip and the second semiconductor chip, electrically connecting the first semiconductor chip and the second semiconductor chip,
wherein the second connection member comprises a second ground connection member connected to a ground portion, the first conductive layer is connected to the second ground connection member, and the second conductive layer is connected to the first conductive layer.

11. The semiconductor package of claim 10, wherein the second conductive layer is connected to the first conductive layer through a conductive wire.

12. The semiconductor package of claim 10, wherein the first conductive layer is in contact with the second ground connection member.

13. The semiconductor package of claim 12, wherein the second connection member further comprises a second signal connection member, and the first conductive layer is not in contact with the second signal connection member.

14. A semiconductor package comprising:
a substrate,
a first semiconductor chip formed on a top surface of the substrate and electrically connected to the substrate by a first connection member, and
a second semiconductor chip formed on a top surface of the first semiconductor chip and electrically connected to the first semiconductor chip by a second connection member,
wherein a first conductive layer and a second conductive layer are formed on the top surfaces of the first semiconductor chip and the second semiconductor chip, respectively, a third conductive layer connected to a ground portion is formed on the top surface of the substrate, and the first conductive layer or the second conductive layer is connected to the third conductive layer.

15. The semiconductor package of claim 14, wherein the first semiconductor chip is electrically connected to the substrate by a first connection member, the first connection member includes a first ground connection member connected to the ground portion, and the third conductive layer is connected to the first ground connection member.

16. The semiconductor package of claim 14, wherein the first conductive layer or the second conductive layer is connected to the third conductive layer through a conductive wire.

17. A semiconductor package comprising:
a substrate,
a first chip disposed over a substrate;
a grounded conductive plate disposed over the first chip, the grounded conductive plate comprising a plurality of openings; and
a second chip disposed over the grounded conductive plate and electrically connected to the first chip through a plurality of conductors disposed between the second chip and the first chip,
wherein the plurality of conductors are disposed in the plurality openings of the grounded conductive plate and not electrically connected to the grounded conductive plate so that the grounded conductive plate substantially blocks electromagnetic waves generated by the first chip, from the second chip.

18. The semiconductor package of claim 17, wherein the grounded conductive plate is connected to a ground of the substrate.

19. The semiconductor package of claim 18 further comprising another grounded conductive plate disposed between the substrate and the first chip, which blocks electromagnetic waves generated by the substrate, from the first chip.
